(19) United States
(12) Patent Application Publication
(10) Pub. No.: US 2026/0327474 A1
(43) Pub. Date: Oct. 22, 2026

(54) COMPOSITE HEAT SINK AND PREPARATION METHOD THEREOF

(71) Applicant: DONGUAN ZIITEK ELECTRONICAL MATERIAL AND TECHNOLOGY LTD., Dongguan City (CN)

(72) Inventors: Chihsheng LIAO, Dongguan City (CN); Alfred GU, Dongguan City (CN)

(21) Appl. No.: 19/331,572

(22) Filed: Sep. 17, 2025

(30) Foreign Application Priority Data
Apr. 22, 2025 (CN) 202510509430.4

(51) Int. Cl. C09K 5/14; C22C 28/00

(52) U.S. Cl. CPC C09K 5/14; C22C 28/00

(57) ABSTRACT

Provided are a composite heat sink and a preparation method thereof. The composite heat sink, which comprises a metal substrate, a hollow protective layer, and a heat-conduction interface layer; the hollow protective layer is arranged at peripheral edges of the metal substrate; the heat-conduction interface layer is soldered and fixed on a surface of the metal substrate which is not covered with the hollow protective layer by fluxing agent. By using a fluxing agent to directly solder the heat-conduction interface layer to a surface of the metal substrate, the one-piece molding further improves the strength of the obtained composite heat sink; and by removing the oxidized layer on the surface of the metal substrate with the assistance of the fluxing agent, a further reduction of thermal impedance is achieved.

### PRIORITY CLAIM

This application claims priority to Chinese Patent Application Serial No. 202510509430.4 filed on Apr. 22, 2025, the contents of which are incorporated herein in its entirety by reference.

### TECHNICAL FIELD

The present application belongs to the technical field of heat dissipation materials, and specifically relates to a composite heat sink and a preparation method thereof.

### BACKGROUND

In the technical field of heat dissipation, an efficient heat dissipation structure is crucial for the stable performance and life extension of various electronic devices. The connection method between the heat sink and the heat dissipation material and the optimization of the related performance have been the key direction of research.

Currently, there are various technical solutions for connecting heat dissipation materials to heat sinks. For example, CN 119328412A discloses a soldering-processing device for a panel-type radiator, which focuses on the soldering-processing of a panel-type radiator. The height is adjusted according to the size of the heat sink by the adjustable part of the mounting base, and the protective part is inserted into the teeth clearance of the heat sink to limit displacement and prevent deformation, and conduct the heat of the soldering in order to improve the efficiency of the heat dissipation at the same time. However, the solution mainly focuses on improving the structural soldering of panel-type radiators, and does not involve the use of specific phase transition metal materials and the use of a fluxing agent to optimize the soldering effect and reduce the thermal impedance, and there is a certain limitation in the selection of connection materials and the control of thermal impedance.

CN 222509602U discloses a PCB structure with a heat dissipation pad, and the heat dissipation structure adopts a non-soldering connection between the heat dissipation body and the heat dissipation base, which can avoid the residue problem of the fluxing agent caused by soldering, but this connection cannot form a strong metallurgical bond like soldering, and the connection strength is far less than that of connecting the phase transition metal and the heat dissipation pad through soldering, so it is difficult to meet the high requirements for connection strength in application scenarios.

In terms of the use of brazing materials, Prof. Guo Fu et al. indicates in “Research advances and prospect of low temperature Sn-xBi-yM alloy solders for microelectronic packaging” (Rare Metal Materials and Engineering, 53(4), 1181-1194) that, although Sn—Bi alloy brazing materials have the characteristics of low melting point, low cost, good wettability, and mechanical strength, there are problems of brittle Bi phase segregation which is not conducive to the long-term service reliability of the device. Current research mainly focuses on reducing the Bi content in brazing materials and alloying, but has not yet been involved in the soldering of Sn—In—Bi phase transition metal and heat sinks and the use of fluxing agent to enhance the overall performance of the technical path. There is a blank area in solving the synergistic optimization of multiple aspects such as soldering strength, thermal impedance, and long-term service reliability of heat sinks and phase transition metals.

In summary, in the choice of connection materials, the optimization of connection manner and the enhancement of comprehensive performance, none of the existing technical solutions of connecting heat sinks can achieve the technical effects of high strength, non-shedding and reduced thermal impedance that can be achieved by soldering phase transition metals directly onto heat sinks through the fluxing agent. It is urgent to fill this blank with a new technical solution to meet the growing demand for efficient heat dissipation structures.

### SUMMARY

The present application relates to a composite heat sink and a preparation method thereof. In the present application, by using a fluxing agent to directly solder the heat-conduction interface layer to a surface of the metal substrate, the one-piece molding further improves the strength of the obtained composite heat sink; and by removing the oxidized layer on the surface of the metal substrate with the assistance of the fluxing agent, a further reduction of thermal impedance is achieved.

In a first aspect, the present application provides a composite heat sink, and the composite heat sink comprises a metal substrate, a hollow protective layer, and a heat-conduction interface layer;
the hollow protective layer is arranged at peripheral edges of the metal substrate; the heat-conduction interface layer is soldered and fixed on a surface of the metal substrate which is not covered with the hollow protective layer by fluxing agent.

In the present application, during the soldering process, the active agent in the fluxing agent has a chemical reaction with oxides on the surface of the metal substrate, and converts the oxides into soluble or volatile substances, thereby removing the oxidation layer, enabling the heat-conduction interface layer to be in direct contact with the surface of the metal substrate; after the removal of the oxidation layer, the fluxing agent forms a protective film on the surface of the metal substrate, which insulates the air and prevents the metal from being oxidized again during the soldering process, thus ensuring the soldering quality;
in addition, as the fluxing agent removes the oxidation layer on the surface of the metal substrate, a good metal-to-metal direct contact between the heat-conduction interface layer and the metal substrate is achieved, which further improves the efficiency of heat conduction and reduces the obstruction of heat transfer at the interface, thus reducing the thermal impedance. If the fluxing agent is not used to assist soldering, in the soldering process, the substrate has an uneven surface, the presence of impurities or oxidation layer, which may lead to small gaps or voids between the solder used for soldering and the metal substrate, thereby increasing the thermal resistance, and the use of fluxing agent can make the solder to fill in the gaps or voids to achieve the close combination of the heat-conduction interface layer and the metal substrate, further reducing the thermal impedance.

As a preferred technical solution of the present application, a material of the metal substrate comprises aluminum or copper.

Preferably, a thickness of the metal substrate is 2 to 10 mm, which may be, for example, 2 mm, 4 mm, 6 mm, 8 mm or 10 mm, etc.; however, the thickness is not limited to the listed values, and other unlisted values within the value range are also applicable.

Preferably, a material of the hollow protective layer comprises any one of photoresist, a PI film or a PET film.

Preferably, a width of the hollow protective layer is 1-50 mm, which may be, for example, 1 mm, 5 mm, 10 mm, 20 mm, 30 mm, 40 mm, or 50 mm, etc.; however, the width is not limited to the listed values, and other unlisted values within the value range are also applicable.

Preferably, a thickness of the hollow protective layer is 0.01-2.0 mm, which may be, for example, 0.01 mm, 0.05 mm, 0.1 mm, 0.5 mm, 1 mm, 1.5 mm, or 2 mm, etc.; however, the thickness is not limited to the listed values, and other unlisted values within the value range are also applicable, preferably 0.05-1 mm.

In the present application, the hollow protective layer is arranged at the peripheral edges of the metal substrate, whose reason is: a size of the heat dissipation fins is usually slightly larger than a size of the wafer, and the metal phase change heat-conduction material only needs a thin layer to fill the gap, so it is not necessary to bond the whole surface of the heat dissipation fins with a phase transition metal material to avoid short circuit caused by the overflowing of excess heat-conduction metal when the metal is above the melting point.

Preferably, a thickness of the heat-conduction interface layer is 0.05-0.5 mm, which may be, for example, 0.05 mm, 0.1 mm, 0.2 mm, 0.3 mm, 0.4 mm, or 0.5 mm, etc.; however, the thickness is not limited to the listed values, and other unlisted values within the value range are also applicable.

In the present application, the thickness of the heat-conduction interface layer is 0.05-0.5 mm, and if the thickness is thick, it will lead to the fact that when the operating temperature reaches the melting point, an excessive amount of liquefied metal will be easily remained on the main board, resulting in short circuit; on the contrary, if the thickness is thin, it will lead to a poor heat conduction effect and an abnormal rise in thermal impedance because the volume of the phase transition metal material is insufficient to fill the gap between it and the wafer.

Preferably, a phase transition temperature of the heat-conduction interface layer is 50-80° C., which may be, for example, 50° C., 55° C., 60° C., 65° C., 70° C., 75° C., or 80° C., etc.; however, the phase transition temperature is not limited to the listed values, and other unlisted values within the value range are also applicable.

Preferably, a material of the heat-conduction interface layer comprises a Sn—In—Bi phase transition alloy.

In the present application, the material of the heat-conduction interface layer comprises a Sn—In—Bi phase transition alloy with a phase transition temperature of 52-70° C. The alloy is solid within the phase transition temperature, and becomes liquid when the temperature is higher than the phase transition temperature, so as to realize the filling of the interface gap, and thus substantially reduce the interface thermal resistance.

In a second aspect, the present application provides a preparation method for the composite heat sink according to the first aspect, and the preparation method comprises the following steps: providing a hollow protective layer at peripheral edges of a metal substrate, and then coating a fluxing agent in an area which is not covered by the hollow protective layer; and then carrying out a dip-soldering treatment to form a heat-conduction interface layer, and cooling to obtain the composite heat sink.

In the present application, the fluxing agent plays a role on the surface of the metal substrate during the dip-soldering process, removes the oxide layer and reduces the surface tension, so that the solder in the molten state used in the dip-soldering process can fully infiltrate the metal substrate, and after the cooling and solidification, a strong metallurgical bonding layer is formed between the metal substrate and the heat-conduction interface layer, and the bonding layer contains a transition region constituted by the residual fluxing agent constituent and the solder alloying products, ensuring that the heat-conduction interface layer is closely adhered to the surface of the metal substrate, and realizing the reduction of the thermal impedance of the composite heat sink.

As a preferred technical solution of the present application, a coating thickness of the fluxing agent is 0.04-0.5 mm, which may be, for example, 0.04 mm, 0.1 mm, 0.2 mm, 0.3 mm, 0.4 mm, or 0.5 mm, etc.; however, the coating thickness is not limited to the listed values, and other unlisted values within the value range are also applicable.

Preferably, an acid value of the fluxing agent is 10-70 mgKOH/g, which may be, for example, mgKOH/g, 20 mgKOH/g, 30 mgKOH/g, 40 mgKOH/g, 50 mgKOH/g, 60 mgKOH/g, or 70 mgKOH/g, etc.; however, the acid value is not limited to the listed values, and other unlisted values within the value range are also applicable, preferably 30-60 mgKOH/g.

Preferably, the fluxing agent has a halogen content of ≤1800 ppm, which may be, for example, 1800 ppm, 1600 ppm, 1400 ppm, 1200 ppm, or 1000 ppm, etc.; however, the halogen content is not limited to the listed values, and other unlisted values within the value range are also applicable.

It should be noted that when the halogen element is chlorine or bromine, the content is less than 900 ppm in both cases.

In the present application, the acid value of the fluxing agent is 10-70 mgKOH/g. If the acid value is high, it will lead to the corrosion of the metal substrate and excessive acid residue, resulting in the phase transition metal having been oxidized and deteriorated in the use process; if the acid value is low, it will lead to insufficient ability to remove the oxides on the surface of the metal substrate, so that the phase transition metal cannot be soldered on the metal substrate completely.

Preferably, by mass fraction, the fluxing agent comprises 0.1-0.3 wt % of ammonium halide, 5-40 wt % of an organic acid, 5-30 wt % of an organic amine, 10-60 wt % of a rosin mixture, 0.1-20 wt % of an organic solvent mixture, and 0.1-3.0 wt % of an assistant.

Exemplarily, in the fluxing agent, a content of the ammonium halide is 0.1-0.3 wt %, which may be, for example, 0.1 wt %, 0.2 wt %, or 0.3 wt %, etc.; however, the content is not limited to the listed values, and other unlisted values within the value range are also applicable;
a content of the organic acid is 5~40 wt %, which may be, for example, 5 wt %, 10 wt %, 20 wt %, 30 wt %, or 40 wt %, etc.; however, the content is not limited to the listed values, and other unlisted values within the value range are also applicable;
a content of the organic amine is from 5 to 30 wt %, which may be, for example, 5 wt %, 10 wt %, 20 wt %, 25 wt %, or 30 wt %, etc.; however, the content is not limited to the listed values, and other unlisted values within the value range are also applicable;
a content of the rosin mixture is 10-60 wt %, which may be, for example, 10 wt %, 20 wt %, 30 wt %, 40 wt %, 50 wt %, or 60 wt %, etc.; however, the content is not limited to the listed values, and other unlisted values within the value range are also applicable;
a content of the organic solvent mixture is 0.1-20 wt %, which may be, for example, 0.1 wt %, 1 wt %, 5 wt %, 10 wt %, 15 wt %, or 20 wt %, etc.; however, the content is not limited to the listed values, and other unlisted values within the value range are also applicable;
a content of the assistant is 0.1-3.0 wt %, which may be, for example, 0.1 wt %, 1 wt %, 1.5 wt %, 2 wt %, 2.5 wt %, or 3 wt %, etc.; however, the content is not limited to the listed values, and other unlisted values within the value range are also applicable.

Preferably, the ammonium halide comprises ammonium chloride and/or ammonium bromide.

Preferably, the organic acid comprises any one or a combination of at least two of oxalic acid, malonic acid, butanedioic acid, adipic acid, tartaric acid, ethylenediaminetetraacetic acid, or citric acid, and typical but non-limiting combinations comprise: a combination of oxalic acid and citric acid, a combination of malonic acid, butanedioic acid, and adipic acid, a combination of tartaric acid and ethylenediaminetetraacetic acid, or a combination of oxalic acid, malonic acid, butanedioic acid, adipic acid, tartaric acid, ethylenediaminetetraacetic acid and citric acid.

Preferably, the organic amine comprises any one or a combination of at least two of diethylamine, dipropylamine, triethylamine, tripropylamine, dimethylethylamine, tributylamine, or dimethylhexylamine, and typical but non-limiting combinations comprise: a combination of diethylamine and dipropylamine, a combination of triethylamine and tripropylamine, a combination of triethylamine and dimethylhexylamine, a combination of triethylamine and dimethylhexylamine, a combination of tripropylamine and dimethylhexylamine, a combination of dimethylethylamine, tributylamine, and tributylamine, or a combination of triethylamine, tripropylamine and dimethylhexylamine.

Preferably, the rosin mixture has an acid value of 10-100 mgKOH/g, which may be, for example, 10 mgKOH/g, 20 mgKOH/g, 40 mgKOH/g, 60 mgKOH/g, 80 mgKOH/g, or 100 mgKOH/g, etc.; however, the acid value is not limited to the listed values, and other unlisted values within the value range are also applicable.

Preferably, the rosin mixture comprises hydrogenated rosin and/or esterified rosin.

Preferably, the organic solvent mixture comprises an ester mixture or an ether-alcohol mixture.

Preferably, the ester mixture comprises any one or a combination of at least two of dimethyl carbonate, diethyl carbonate, or ethylene glycol butyl ether acetate, and typical but non-limiting combinations comprise: a combination of dimethyl carbonate and diethyl carbonate, a combination of dimethyl carbonate and ethylene glycol butyl ether acetate, a combination of diethyl carbonate and ethylene glycol butyl ether acetate, or a combination of dimethyl carbonate, diethyl carbonate, and ethylene glycol butyl ether acetate.

Preferably, the ether-alcohol mixture comprises any one or a combination of at least two of diethylene glycol monobutyl ether, diethylene glycol methyl ether or ethylene glycol methyl ether, and typical but non-limiting combinations comprise: a combination of diethylene glycol monobutyl ether and diethylene glycol methyl ether, a combination of diethylene glycol methyl ether and ethylene glycol methyl ether, a combination of diethylene glycol monobutyl ether and ethylene glycol methyl ether, or a combination of diethylene glycol monobutyl ether, diethylene glycol methyl ether, and ethylene glycol methyl ether.

Preferably, the assistant comprises organosilicone and/or an acrylic assistant.

Preferably, the organosilicone is purchased from BYK; the acrylic assistant is purchased from TCI.

Preferably, a solder used for the dip-soldering treatment comprises a Sn—In—Bi phase transition alloy liquid.

Preferably, the dip-soldering treatment is performed at a temperature of 120-180° C., which may be, for example, 120° C., 130° C., 140° C., 150° C., 160° C., 170° C., or 180° C., etc.; however, the temperature is not limited to the listed values, and other unlisted values within the value range are also applicable.

Preferably, the dip-soldering treatment is performed for a period of 10-120 s, which may be, for example, 10 s, 30 s, 50 s, 70 s, 90 s, or 120 s, etc.; however, the period is not limited to the listed values, and other unlisted values within the value range are also applicable.

In the present application, the dip soldering treatment is performed at a temperature of 120-180° C. If the dip-soldering temperature is high, it will lead to the increased oxidation of the metal substrate or directly lead to the deformation of the metal substrate; the period of the dip-soldering treatment should not be too long, otherwise it will damage the metal substrate or lead to the failure of the fluxing agent, the excessive metal oxidation and other problems; the period of the dip-soldering treatment should not be too short, otherwise the Sn—In—Bi phase transition alloy liquid cannot have a sufficient metallurgical bonding with the surface of the metal substrate.

Preferably, by mass fraction, the Sn—In—Bi phase transition alloy liquid comprises: 14-18 wt % tin, 29-35 wt % bismuth, 45-55 wt % indium, 0.1-2 wt % zinc, 0.1-1 wt % magnesium, 0.1-1 wt % copper, and 0-0.02 wt % gallium.

Exemplarily, in the Sn—In—Bi phase transition alloy liquid, a content of tin is 14-18 wt %, which may be, for example, 14 wt %, 15 wt %, 16 wt %, 17 wt %, or 18 wt %, etc.; however, the content is not limited to the listed values, and other unlisted values within the value range are also applicable;
a content of bismuth is 29-35 wt %, which may be, for example, 29 wt %, 30 wt %, 32 wt %, 33 wt %, 34 wt %, or 35 wt %, etc.; however, the content is not limited to the listed values, and other unlisted values within the value range are also applicable;
a content of indium is 45-55 wt %, which may be, for example, 45 wt %, 47 wt %, 49 wt %, 51 wt %, 53 wt %, or 55 wt %, etc.; however, the content is not limited to the listed values, and other unlisted values within the value range are also applicable;
a content of zinc is 0.1-2 wt %, which may be, for example, 0.1 wt %, 0.5 wt %, 1 wt %, 1.5 wt %, or 2 wt %, etc.; however, the content is not limited to the listed values, and other unlisted values within the value range are also applicable;
a content of magnesium is 0.1-1 wt %, which may be, for example, 0.1 wt %, 0.2 wt %, 0.4 wt %, 0.6 wt %, 0.8 wt %, or 1 wt %, etc.; however, the content is not limited to the listed values, and other unlisted values within the value range are also applicable;
a content of copper is 0.1-1 wt %, which may be, for example, 0.1 wt %, 0.2 wt %, 0.4 wt %, 0.6 wt %, 0.8 wt %, or 1 wt %, etc.; however, the content is not limited to the listed values, and other unlisted values within the value range are also applicable;
a content of gallium is 0-0.02 wt %, which may be, for example, 0 wt %, 0.01 wt %, 0.015 wt %, or 0.02 wt %, etc.; however, the content is not limited to the listed values, and other unlisted values within the value range are also applicable.

As a preferred technical solution of the present application, before arranging the hollow protective layer, the preparation method further comprises: subjecting the metal substrate to a pre-treatment.

Preferably, the pre-treatment comprises subjecting the metal substrate to degreasing, cleaning, air-drying, and polishing in sequence.

Preferably, a roughness of the metal substrate obtained after the pre-treatment is 15-50 μm, which may be, for example, 15 μm, 20 μm, 30 μm, 40 μm, or 50 μm, etc.; however, the roughness is not limited to the listed values, and other unlisted values within the value range are also applicable.

As a preferred technical solution of the present application, the preparation method for the composite heat sink according to the first aspect provided in the second aspect of the present application comprises the following steps:
(1) subjecting a metal substrate to a pre-treatment so as to make a roughness of the metal substrate of 15-50 μm; and
(2) arranging a hollow protective layer at peripheral edges of the metal substrate, and then coating a fluxing agent with 0.04-0.5 mm to an area which is not covered with the hollow protective layer; and then under a condition of 120-160° C., subjecting a Sn—In—Bi phase transition alloy liquid to a dip-soldering treatment for 10-120 s to form a heat-conduction interface layer, and cooling to obtain the composite heat sink;
wherein the fluxing agent has an acid value of 10-70 mgKOH/g and a halogen content of ≤1800 ppm;
by mass fraction, the fluxing agent comprises 0.1-0.3 wt % of ammonium halide, 5-40 wt % of an organic acid, 5-30 wt % of an organic amine, 10-60 wt % of a rosin mixture, 0.1-20 wt % of an organic solvent mixture, and 0.1-3.0 wt % of an assistant;
the rosin mixture has an acid value of 10-100 mgKOH/g;
by mass fraction, the Sn—In—Bi phase transition alloy liquid comprises: 14-18 wt % tin, 29-35 wt % bismuth, 45-55 wt % indium, 0.1-2 wt % zinc, 0.1-1 wt % magnesium, 0.1-1 wt % copper, and 0-0.02 wt % gallium.

The numerical ranges in the present application not only comprise the above-listed point values, but also comprise any point values between the above numerical ranges which are not listed, and for the sake of space and brevity, the present application will not exhaustively list the specific point values comprised in the said ranges.

Compared to the prior art, the present application has the following beneficial effects:
(1) the composite heat sink provided by the present application is integrally molded and has better strength, and does not need to be fixed with additional adhesives or other fixtures, and does not need additional processes to increase the plating layer, which can further reduce the cost of processes and materials, and will not cause the risk of falling off due to vibration during the transportation;
(2) the composite heat sink provided by the present application has a heat-conduction interface layer with a high heat conductivity and is liquefied during the actual use, and the thickness of the heat sink can be reduced in the extreme due to being compressed and is not controlled by gaskets or heat-conduction powders, which further reduces the thermal impedance;
(3) in the present application, by cleaning between the metal substrate and the heat-conduction interface layer with the fluxing agent, the residues of oxides and small voids are removed, and the thermal impedance can be further reduced; and
(4) in the present application, by forming an intermetallic compound between the metal substrate and the heat-conduction interface layer by the fluxing agent, the acting force and adsorption force between the metal substrate and the heat-conduction interface layer are further increased, and the risk of overflow after the liquefaction of the heat-conduction interface layer is further reduced.

### BRIEF DESCRIPTION OF DRAWINGS

FIG. 1 is a top view of the composite heat sink provided in Example 1 of the present application;

FIG. 2 is a sectional view of the composite heat sink provided in Example 1 of the present application;

reference list: 1—metal substrate, 2—hollow protective layer, and 3—heat-conduction interface layer.

### DETAILED DESCRIPTION

The technical solutions of the present application are further described below by way of specific embodiments. It should be clear to those skilled in the art that the examples are merely an aid to understanding the application and should not be regarded as a specific limitation of the application.

### Example 1

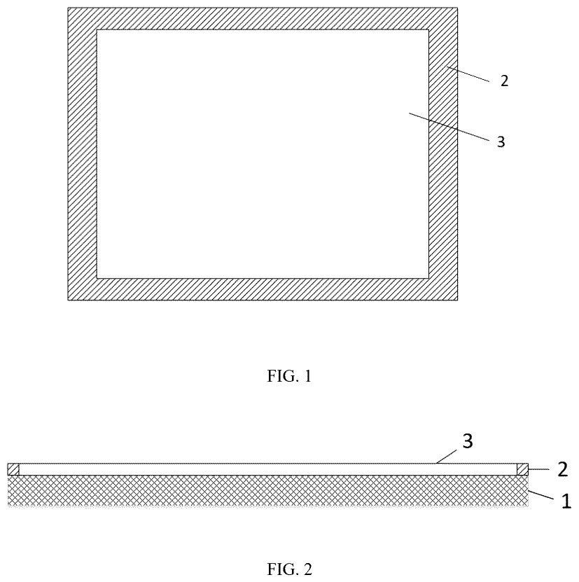

This example provides a composite heat sink, as shown in FIGS. 1 and 2, wherein the composite heat sink comprises a metal substrate 1, a hollow protective layer 2, and a heat-conduction interface layer 3;
the hollow protective layer 2 is provided at the peripheral edges of the metal substrate 1; the heat-conduction interface layer 3 is soldered and fixed on a surface of the metal substrate 1 which is not covered with the hollow protective layer 2 by fluxing agent.

The metal substrate 1 is made of aluminum with a thickness of 6 mm; the hollow protective layer 2 is made of a PI film with a width of 10 mm and a thickness of 0.15 mm; and the heat-conductive interface layer 3 has a thickness of 0.25 mm and is made of a Sn—In—Bi phase transition alloy.

The preparation method for the composite heat sink comprises the following steps:
(1) a metal substrate was subjected to a pre-treatment so as to make a roughness of the metal substrate of 20 μm; and
(2) a hollow protective layer was arranged at the peripheral edges of the metal substrate, and then an area which was not covered by the hollow protective layer was coated with 0.3 mm of a fluxing agent; and then under a condition of 150° C., a Sn—In—Bi phase transition alloy liquid was subjected to a dip-soldering treatment for 40 s to form a heat-conduction interface layer, and cooled to obtain the composite heat sink;
wherein the fluxing agent had an acid value of 20 mgKOH/g and a halogen content of 900 ppm;
by mass fraction, the fluxing agent comprised 0.13 wt % of ammonium chloride, 30 wt % of an organic acid (oxalic acid), 20 wt % of an organic amine (a combination of triethylamine and tripropylamine), 35 wt % of a rosin mixture (hydrogenated rosin), 12.5 wt % of an organic solvent mixture (an ester mixture), and 2 wt % of organosilicone;
the rosin mixture had an acid value of 55 mgKOH/g;
by mass fraction, the Sn—In—Bi phase transition alloy liquid comprised: 16 wt % tin, 32 wt % bismuth, 50 wt % indium, 0.5 wt % zinc, 0.5 wt % magnesium, and 1 wt % copper.

### Example 2

This example provides a composite heat sink, wherein the composite heat sink comprises a metal substrate, a hollow protective layer, and a heat-conduction interface layer; the hollow protective layer is provided at the peripheral edges of the metal substrate; the heat-conduction interface layer is soldered and fixed on a surface of the metal substrate which is not covered with the hollow protective layer by fluxing agent.

The metal substrate is made of copper with a thickness of 2 mm; the hollow protective layer 2 is made of photoresist with a width of 15 mm and a thickness of 0.5 mm; and the heat-conductive interface layer has a thickness of 0.05 mm and is made of a Sn—In—Bi phase transition alloy.

The preparation method for the composite heat sink comprises the following steps:
(1) a metal substrate was subjected to a pre-treatment so as to make a roughness of the metal substrate of 40 μm; and
(2) a hollow protective layer was arranged at the peripheral edges of the metal substrate, and then an area which was not covered by the hollow protective layer was coated with 0.04 mm of a fluxing agent; and then under a condition of 120° C., a Sn—In—Bi phase transition alloy liquid was subjected to a dip-soldering treatment for 120 s to form a heat-conduction interface layer, and cooled to obtain the composite heat sink;
wherein the fluxing agent had an acid value of 50 mgKOH/g and a halogen content of 800 ppm;
by mass fraction, the fluxing agent comprised 0.1 wt % of ammonium bromide, 40 wt % of an organic acid (a combination of malonic acid, butanedioic acid, and adipic acid), 5 wt % of an organic amine (dimethylhexylamine), 54.3 wt % of a rosin mixture (esterified rosin), 0.5 wt % of an ether-alcohol mixture, and 0.1 wt % of an acrylic assistant;
the rosin mixture had an acid value of 20 mgKOH/g;
by mass fraction, the Sn—In—Bi phase transition alloy liquid comprised: 14 wt % tin, 35 wt % bismuth, 46.96 wt % indium, 2 wt % zinc, 1 wt % magnesium, 1 wt % copper, and 0.02 wt % gallium.

### Example 3

This example provides a composite heat sink, wherein the composite heat sink comprises a metal substrate, a hollow protective layer, and a heat-conduction interface layer;
the hollow protective layer is provided at the peripheral edges of the metal substrate; the heat-conduction interface layer is soldered and fixed on a surface of the metal substrate which is not covered with the hollow protective layer by fluxing agent.

The metal substrate is made of aluminum with a thickness of 10 mm; the hollow protective layer is made of a PI film with a width of 40 mm and a thickness of 0.8 mm; and the heat-conductive interface layer has a thickness of 0.5 mm and is made of a Sn—In—Bi phase transition alloy.

The preparation method for the composite heat sink comprises the following steps:
(1) a metal substrate was subjected to a pre-treatment so as to make a roughness of the metal substrate of 60 μm; and
(2) a hollow protective layer was arranged at the peripheral edges of the metal substrate, and then an area which was not covered by the hollow protective layer was coated with 0.5 mm of a fluxing agent; and then under a condition of 180° C., a Sn—In—Bi phase transition alloy liquid was subjected to a dip-soldering treatment for 20 s to form a heat-conduction interface layer, and cooled to obtain the composite heat sink;
wherein the fluxing agent had an acid value of 40 mgKOH/g and a halogen content of 1800 ppm;
by mass fraction, the fluxing agent comprised 1 wt % of ammonium chloride, 5 wt % of citric acid, 30 wt % of dimethylhexylamine, 41 wt % of a rosin mixture (hydrogenated rosin and esterified rosin), 20 wt % of an ester mixture, and 3 wt % of organosilicone;
the rosin mixture had an acid value of 100 mgKOH/g;
by mass fraction, the Sn—In—Bi phase transition alloy liquid comprised: 15.69 wt % tin, 29 wt % bismuth, 55 wt % indium, 0.1 wt % zinc, 0.1 wt % magnesium, 0.1 wt % copper, and 0.01 wt % gallium.

### Example 4

This example provides a composite heat sink, and the composite heat sink is the same as Example 1.

The preparation method for the composite heat sink differs from Example 1 only in that: in this example, the coating thickness of the fluxing agent in step (2) was adjusted to 0.02 mm.

### Example 5

This example provides a composite heat sink, and the composite heat sink is the same as Example 1.

The preparation method for the composite heat sink differs from Example 1 only in that: in this example, the coating thickness of the fluxing agent in step (2) was adjusted to 0.7 mm.

### Example 6

This example provides a composite heat sink, and the composite heat sink is the same as Example 1.

The preparation method for the composite heat sink differs from Example 1 only in that: in this example, the acid value of the fluxing agent in step (2) was adjusted to 80 mgKOH/g.

### Example 7

This example provides a composite heat sink, and the composite heat sink is the same as Example 1.

The preparation method for the composite heat sink differs from Example 1 only in that: in this example, the acid value of the fluxing agent in step (2) was adjusted to 2 mgKOH/g.

### Example 8

This example provides a composite heat sink, and the composite heat sink differs from Example 1 only in that:
in this example, the thickness of the heat-conduction interface layer is adjusted to 0.02 mm.

The preparation method for the composite heat sink is the same as that of Example 1.

### Example 9

This example provides a composite heat sink, and the composite heat sink differs from Example 1 only in that:
in this example, the thickness of the heat-conduction interface layer is adjusted to 0.8 mm.
The preparation method for the composite heat sink is the same as that of Example 1.

### Comparative Example 1

This comparative example provides a composite heat sink, and the composite heat sink differs from Example 1 only in that:
in this comparative example, the hollow protective layer arranged at the peripheral edge of the metal substrate is omitted.

### Comparative Example 2

This comparative example provides a composite heat sink, and the composite heat sink differs from Example 1 only in that:
in this comparative example, the heat-conduction interface layer is fixed in an area of the surface of the metal substrate which is not covered with the hollow protective layer by electron beam soldering.

The electron beam soldering has an input current of 80 mA, a focal current of 500 mA, and a line speed of 15 mm/s.

### Comparative Example 3

This comparative example provides a composite heat sink, and the composite heat sink differs from Example 1 only in that:

The preparation method for the heat-conduction interface layer in this comparative example comprises: a Sn—In—Bi phase transition alloy liquid is arranged on an area of the metal substrate surface which is not covered with the hollow protective layer by a coating process.

### Performance Test

The composite heat sinks provided in the above examples and in comparative examples were subjected to the soldering strength test and the thermal impedance test, the results of which are shown in Table 1.

The soldering strength was tested with a universal tensile machine and a push-pull gauge; the thermal impedance was tested with ASTM D5470 steady state method.

TABLE 1

| | Soldering | Thermal impedance |
|---|---|---|
| | strength (MPa) | (K · in²/W) |
| Example 1 | 35 | 0.011 |
| Example 2 | 33 | 0.008 |
| Example 3 | 36 | 0.007 |
| Example 4 | 18 | 0.286 |
| Example 5 | 20 | 0.172 |
| Example 6 | 15 | 0.371 |
| Example 7 | 5 | 0.522 |
| Example 8 | 8 | 0.411 |
| Example 9 | 34 | 0.108 |
| Comparative Example 1 | 33 | 0.086 |
| Comparative Example 2 | 9 | 0.535 |
| Comparative Example 3 | 3 | 0.839 |

According to Table 1, the following can be seen.
(1) The comprehensive analysis of Examples 1-3 shows that the composite heat sink provided by the present application has excellent soldering strength and low thermal impedance.
(2) The comprehensive analysis of Example 1 and Examples 4-5 shows that if the coating thickness of the fluxing agent is relatively thick, it will cause the solder to be relatively insufficient and prone to over-oxidization, resulting in partially empty soldering; conversely, if the coating thickness of the fluxing agent is relatively thin, it will lead to the oxides on the metal layer surface failing to be removed cleanly, resulting in the phenomenon of empty soldering.
(3) The comprehensive analysis of Example 1 and Examples 6-7 shows that the acid value of the fluxing agent affects the removing effect of surface oxides and the stability after the soldering; if the acid value of the fluxing agent is high, it will lead to excessive acid residue after soldering, which affects the stability and contributes to the deterioration of strength and the increase of thermal impedance; on the contrary, if the acid value of the fluxing agent is low, it will lead to the failure of removing surface oxides on the metal layer, resulting in the phenomenon of empty soldering.
(4) The comprehensive analysis of Example 1 and Examples 8-9 shows that if the thickness of the heat-conduction interface layer is relatively thick, it will lead to an increase in thermal impedance; conversely, if the thickness of the heat-conduction interface layer is relatively thin, it will lead to insufficient solder, resulting in empty soldering and an increase in thermal impedance.
(5) The comprehensive analysis of Example 1 and Comparative Example 1 shows that the omission of the hollow protective layer will result in excessive solder and increased thermal impedance, and in actual use, the excessive solder will flow to areas that are outside of the chip, causing the circuit board to short-circuit.
(6) The comprehensive analysis of Example 1 and Comparative Example 1 shows that the presence of the fluxing agent is one of the important factors for reducing the thermal impedance, and the use of the electron beam soldering or coating process results in the incomplete soldering due to the absence of fluxing agent to assist in the removal of surface oxides, resulting in empty soldering or even easy to fall off.

In summary, in the present application, by using a fluxing agent to directly solder the heat-conduction interface layer to a surface of the metal substrate, the one-piece molding further improves the strength of the obtained composite heat sink; and by removing the oxidized layer on the surface of the metal substrate with the assistance of the fluxing agent, achieving a further reduction of thermal impedance.

The applicant declares that the above description is only a specific embodiment of the present application, but the protection scope of the present application is not limited thereto, and it should be clear to those skilled in the art that any changes or substitutions, which can be readily thought of by a person skilled in the art within the technical scope of the present application disclosed herein, shall fall within the protection scope and the disclosure scope of the present application.

What is claimed is:

1. A composite heat sink, comprising:
a metal substrate;
a hollow protective layer; and
a heat-conduction interface layer,
wherein the hollow protective layer is arranged at peripheral edges of the metal substrate; and
wherein the heat-conduction interface layer is soldered and fixed on a surface of the metal substrate which is not covered with the hollow protective layer by fluxing agent.

2. The composite heat sink according to claim 1, wherein a material of the metal substrate comprises aluminum or copper.

3. The composite heat sink according to claim 1, wherein a thickness of the metal substrate is 2 to 10 mm.

4. The composite heat sink according to claim 1, wherein a material of the hollow protective layer comprises any one of photoresist, a PI film, or a PET film.

5. The composite heat sink according to claim 1, wherein a width of the hollow protective layer is 1-50 mm.

6. The composite heat sink according to claim 1, wherein a thickness of the hollow protective layer is 0.01-2.0 mm, and preferably 0.05-1 mm.

7. The composite heat sink according to claim 1, wherein a thickness of the heat-conduction interface layer is 0.05-0.5 mm.

8. The composite heat sink according to claim 1, wherein a phase transition temperature of the heat-conduction interface layer is 50-80° C.

9. The composite heat sink according to claim 1, wherein a material of the heat-conduction interface layer comprises a Sn—In—Bi phase transition alloy.

10. A preparation method for a composite heat sink, comprising:
providing a hollow protective layer of the sink at a peripheral edge of a metal substrate of the sink;
coating a fluxing agent in an area which is not covered with the hollow protective layer;
carrying out a dip-soldering treatment to form a heat-conduction interface layer of the sink; and
cooling to obtain the sink.

11. The preparation method according to claim 10, wherein a coating thickness of the fluxing agent is 0.04-0.5 mm; preferably, an acid value of the fluxing agent is 10-70 mgKOH/g, and preferably, 30-60 mgKOH/g; preferably, the fluxing agent has a halogen content of ≤1800 ppm.

12. The preparation method according to claim 11, wherein by mass fraction, the fluxing agent comprises 0.1-0.3 wt % of ammonium halide, 5-40 wt % of an organic acid, 5-30 wt % of an organic amine, 10-60 wt % of a rosin mixture, 0.1-20 wt % of an organic solvent mixture, and 0.1-3.0 wt % of an assistant.

13. The preparation method according to claim 12, wherein the ammonium halide comprises ammonium chloride and/or ammonium bromide.

14. The preparation method according to claim 12, wherein the organic acid comprises any one or a combination of at least two of oxalic acid, malonic acid, butanedioic acid, adipic acid, tartaric acid, ethylenediaminetetraacetic acid, or citric acid.

15. The preparation method according to claim 12, wherein the organic amine comprises any one or a combination of at least two of diethylamine, dipropylamine, triethylamine, tripropylamine, dimethylethylamine, tributylamine, or dimethylhexylamine.

16. The preparation method according to claim 12, wherein the rosin mixture has an acid value of 10-100 mgKOH/g; preferably, the rosin mixture comprises hydrogenated rosin and/or esterified rosin.

17. The preparation method according to claim 12, wherein the organic solvent mixture comprises an ester mixture or an ether-alcohol mixture; preferably, the assistant comprises organosilicone and/or an acrylic assistant.

18. The preparation method according to claim 10, wherein a solder used for the dip-soldering treatment comprises a Sn—In—Bi phase transition alloy liquid; preferably, the dip-soldering treatment is performed at a temperature of 120-180° C.; preferably, the dip soldering treatment is performed for a period of 10-120 s.

19. The preparation method according to claim 18, wherein by mass fraction, the Sn—In—Bi phase transition alloy liquid comprises: 14-18 wt % tin, 29-35 wt % bismuth, 45-55 wt % indium, 0.1-2 wt % zinc, 0.1-1 wt % magnesium, 0.1-1 wt % copper, and 0-0.02 wt % gallium.

20. The preparation method according to claim 10, wherein before arranging the hollow protective layer, the preparation method further comprises: subjecting the metal substrate to a pre-treatment; preferably, the pre-treatment comprises subjecting the metal substrate to degreasing, cleaning, air-drying and polishing in sequence; preferably, a roughness of the metal substrate obtained after the pre-treatment is 15-50 μm.
